(19) United States
(12) Patent Application Publication
(10) Pub. No.: US 2024/0260359 A1
(43) Pub. Date: Aug. 1, 2024

(54) ORGANIC LIGHT EMITTING DIODE DISPLAY DEVICE INCLUDING MEASUREMENT HOLE AND METHOD OF FABRICATING THE SAME

(71) Applicant: LG Display Co., Ltd., Seoul (KR)

(72) Inventor: Bong-Jun KIM, Paju-si (KR)

(73) Assignee: LG Display Co., Ltd., Seoul (KR)

(21) Appl. No.: 18/520,166

(22) Filed: Nov. 27, 2023

(30) Foreign Application Priority Data
Jan. 26, 2023 (KR) 10-2023-0010298

(51) Int. Cl. H10K 59/131; G01B 11/06; H10K 59/12; H10K 59/80

(52) U.S. Cl. CPC H10K 59/131; G01B 11/0616; H10K 59/1201; H10K 59/879

(57) ABSTRACT

An organic light emitting diode display device includes a subpixel on a substrate, and a circuit part in the subpixel on the substrate. Further, a plurality of conductive lines are connected to the circuit part, and an overcoat layer is disposed on the plurality of conductive lines. The overcoat layer has a measurement hole corresponding to at least one of the plurality of conductive lines. Also, a light emitting diode connected to the circuit part is disposed on the overcoat layer.

### CROSS-REFERENCE TO RELATED APPLICATIONS

The present application claims the priority benefit of Korean Patent Application No. 10-2023-0010298, filed in Republic of Korea on Jan. 26, 2023, which is hereby incorporated by reference in its entirety into the present application.

### BACKGROUND

### Technical Field

The present disclosure relates to a display device, and more particularly, to an organic light emitting diode display device where accurate measurement and management (e.g., monitoring) for a thickness of a photoresist pattern are obtained due to a measurement hole.

### Discussion of the Related Art

With the advent of an information-oriented society, the interest in information displays for processing and displaying a massive amount of information and the demand for portable information media have increased. As such, a display field has rapidly advanced. Thus, various light and thin flat panel display devices have been developed and highlighted.

Among the various flat panel display devices, an organic light emitting diode (OLED) display device is a self-emissive type device that does not include a backlight unit used in a non-self-emissive type device such as a liquid crystal display (LCD) device. As a result, the OLED display device has a light weight and a thin profile.

Further, the OLED display device has advantages in a viewing angle, a contrast ratio and a power consumption as compared with the LCD device. The OLED display device is driven with a direct current (DC) low voltage and has a relatively rapid response speed. Since the inner elements of the OLED display device has a solid state, the OLED display device has a relatively strong resistance to an external impact and has a relatively wide temperature range.

In the OLED display device, since the profile of a surface of an overcoat layer is changed according to the thickness of a photoresist pattern, it is needed to manage a uniform thickness of the photoresist pattern. However, since the refractive index of the photoresist pattern is similar to the refractive index of the overcoat layer, it can be challenging to classify the overcoat layer and the photoresist pattern. Further, since the total thickness of the overcoat layer and the photoresist pattern can be relatively large, the measurement of the total thickness of the overcoat layer and the photoresist pattern may not be accurate.

### SUMMARY OF THE DISCLOSURE

Accordingly, the present disclosure is directed to a display device that substantially obviates one or more of the problems due to limitations and disadvantages of the related art.

An object of the present disclosure is to provide an organic light emitting diode display device where accurate measurement and management for the thickness of a photoresist pattern and a process optimization are obtained by forming a measurement hole in an overcoat layer over a power line and measuring a thickness of a photoresist pattern.

Another object of the present disclosure is to provide an organic light emitting diode display device where an ashing rate of a photoresist pattern and an overcoat layer and a total ashing rate of an overcoat layer are calculated and a process optimization are obtained by measuring a thickness of a photoresist pattern in a first measurement hole of an overcoat layer and a thickness of an overcoat layer exposed through a second measurement hole of a photoresist pattern.

Additional features and advantages of the disclosure will be set forth in the description which follows, and in part will be apparent from the description, or can be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, an organic light emitting diode display device includes a substrate having a subpixel; a circuit part in the subpixel on the substrate; a plurality of conductive lines connected to the circuit part; an overcoat layer on the plurality of conductive lines, and having a measurement hole corresponding to at least one of the plurality of conductive lines; and a light emitting diode on the overcoat layer, and connected to the circuit part.

In another aspect, a method of fabricating an organic light emitting diode display device includes forming a circuit part in a subpixel on a substrate; forming a plurality of conductive lines connected to the circuit part; forming an overcoat layer having a measurement hole corresponding to at least one of the plurality of conductive lines on the plurality of conductive lines; and forming a light emitting diode connected to the circuit part on the overcoat layer.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view showing an organic light emitting diode display device according to an embodiment of the present disclosure;

FIG. 2 is an equivalent circuit diagram showing a subpixel of an organic light emitting diode display device according to an embodiment of the present disclosure;

FIG. 3 is a cross-sectional view showing a display panel of an organic light emitting diode display device according to an embodiment of the present disclosure;

FIG. 4 is a plan view showing a pixel of a display panel of an organic light emitting diode display device according to an embodiment of the present disclosure;

FIG. 5 is a cross-sectional view taken along a line V-V of FIG. 4;

FIGS. 6A to 6E are cross-sectional views showing a method of fabricating an organic light emitting diode display device according to an embodiment of the present disclosure; and

FIGS. 7A and 7B are views showing a method of measuring a thickness of an organic light emitting diode display device according to an embodiment of the present disclosure.

### DETAILED DESCRIPTION OF THE EMBODIMENTS

Advantages and features of the present disclosure, and implementation methods thereof will be clarified through following example embodiments described with reference to the accompanying drawings. The present disclosure can, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the present disclosure is only defined by scopes of claims.

The shapes, dimensions, areas, ratios, angles, numbers, and the like, which are illustrated in the drawings to describe various example embodiments of the present disclosure, are merely given by way of example. Therefore, the present disclosure is not limited to the illustrations in the drawings. Like reference numerals generally denote like elements throughout the specification, unless otherwise specified.

Features of various embodiments of the present disclosure can be partially or entirely coupled to or combined with each other and can be operated, linked, or driven together in various ways. Embodiments of the present disclosure can be carried out independently from each other, or can be carried out together in co-dependent or related relationship. In one or more aspects, the components of each organic light emitting diode display device according to various embodiments of the present disclosure can be operatively coupled and configured.

Hereinafter, an organic light emitting diode display device according to embodiments of the present disclosure will be described in detail with reference to the accompanying drawings.

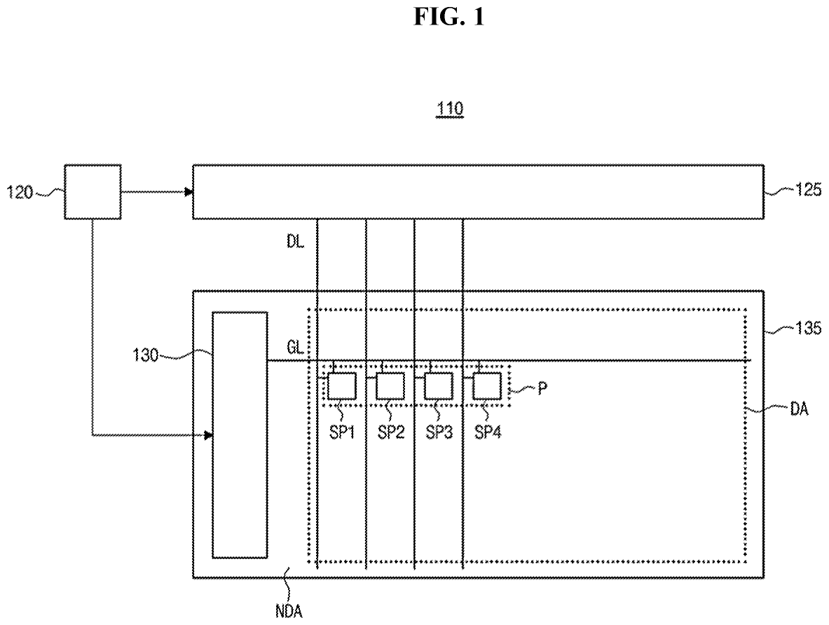

FIG. 1 is a view showing an organic light emitting diode display device according to an embodiment of the present disclosure.

In FIG. 1, an organic light emitting diode (OLED) display device 110 according to an embodiment of the present disclosure includes a timing controlling unit 120, a data driving unit 125, a gate driving unit 130 and a display panel 135.

The timing controlling unit 120 generates an image data, a data control signal and a gate control signal using an image signal and a plurality of timing signals including a data enable signal, a horizontal synchronization signal, a vertical synchronization signal and a clock signal transmitted from an external system such as a graphic card or a television system. The image data and the data control signal are transmitted to the data driving unit 125, and the gate control signal is transmitted to the gate driving unit 130.

The data driving unit 125 generates a data signal (a data voltage) using the data control signal and the image data transmitted from the timing controlling unit 120 and transmits the data signal to a data line DL of the display panel 135.

The gate driving unit 130 generates a gate signal (a gate voltage) using the gate control signal transmitted from the timing controlling unit 120 and supplies the gate signal to a gate line GL of the display panel 135. Further, the gate driving unit 130 can generate an emission signal according to a structure of each subpixel SP1, SP2, SP3 and SP4 and supply the emission signal to the display panel 135.

The gate driving unit 130 can have a gate in panel (GIP) type to be formed in a non-display area NDA of a substrate of the display panel 135 having the gate line GL, the data line DL and a pixel P.

The display panel 135 includes a display area DA at a central portion thereof and a non-display area NDA surrounding the display area DA. As a variation, the non-display area NDA can surround the display area DA completely or only in part. The shapes of the display area DA and the non-display area NDA can vary as well. The display panel 135 displays an image using the gate signal and the data signal. For displaying an image, the display panel 135 includes a plurality of pixels P, a plurality of gate lines GL and a plurality of data lines DL in the display area DA.

Each of the plurality of pixels P includes first, second, third and fourth subpixels SP1, SP2, SP3 and SP4, and the gate line GL and the data line DL cross each other to define the first, second, third and fourth subpixels SP1, SP2, SP3 and SP4. Each of the first, second, third and fourth subpixels SP1, SP2, SP3 and SP4 is connected to the gate line GL and the data line DL.

For example, the first, second, third and fourth subpixels SP1, SP2, SP3 and SP4 can correspond to one of red, green, blue and white colors. However, different colors can be assigned to these sub-pixels. Further, the number of sub-pixels assigned to constitute a pixel can be different from four that is shown in FIG. 1.

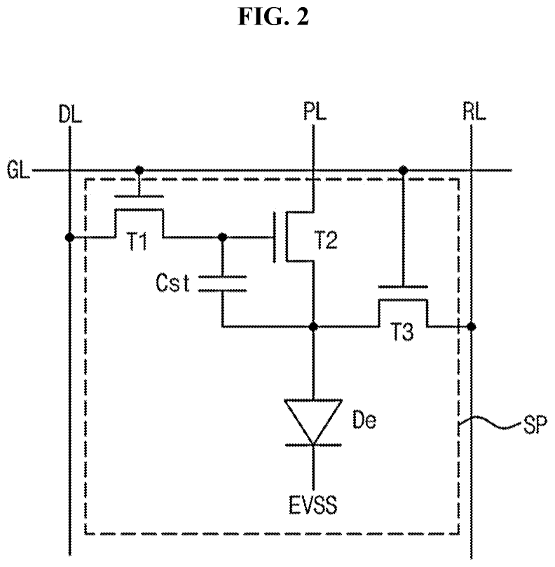

Each of the first, second, third and fourth subpixels SP1, SP2, SP3 and SP4 can include a plurality of thin film transistors (TFTs) such as a switching TFT T1 (of FIG. 2) and a driving TFT T2 (of FIG. 2), a storage capacitor Cst (of FIG. 2) and a light emitting diode De (of FIG. 2). An example illustrated in FIG. 2 represents 3T1C structure that where three transistors and one capacitor are disposed, but embodiments of the present disclosure are not limited to this. For example, 2T1C, 4T1C, 5T1C, 3T2C, 4T2C, 5T2C, 6T2C, 7T1C, 7T2C, 8T1C, 8T2C structures, etc. are also possible. And more or less transistors and capacitors could be included.

FIG. 2 is an equivalent circuit diagram showing a subpixel of an organic light emitting diode display device according to an embodiment of the present disclosure.

In FIG. 2, a subpixel SP (each of SP1 to SP4 of FIG. 1) of an organic light emitting diode display device according to an embodiment of the present disclosure includes a first transistor T1 of a switching transistor, a second transistor T2 of a driving transistor, a third transistor T3 of a sensing transistor, a storage capacitor Cst and a light emitting diode De.

Although the first, second and third transistors T1, T2 and T3 have a negative type in an embodiment of FIG. 2, the first, second and third transistors T1, T2 and T3 can have a positive type in another embodiment.

The gate line GL supplying the gate signal and the data line DL supplying the data signal cross each other, and the first transistor T1 is disposed at crossing of the gate line GL and the data line DL.

A gate electrode of the first transistor T1 is connected to the gate line GL to receive the gate signal, and a drain electrode of the first transistor T1 is connected to the data line DL to receive the data signal.

A gate electrode of the second transistor T2 is connected to a source electrode of the first transistor T1 and a first capacitor electrode of the storage capacitor Cst, a drain electrode of the second transistor T2 is connected to a power line PL supplying a high level voltage, and a source electrode of the second transistor T2 is connected to an anode of the light emitting diode De, a second capacitor electrode of the storage capacitor Cst and a source electrode of the third transistor T3.

A gate electrode of the third transistor T3 is connected to the gate line GL, and a drain electrode of the third transistor T3 is connected to a reference line RL supplying a reference voltage.

In another embodiment, the gate electrode of the third transistor T3 can be connected to an additional sensing line.

Positions of the source and drain electrodes of the first, second and third transistors T1, T2 and T3 are not limited thereto and can be exchanged.

A cathode of the light emitting diode De can be connected to a line supplying a low level voltage or a line supplying a ground voltage.

During an emission period of one frame, the first transistor T1 is switched according to the gate signal transmitted through the gate line GL to supply the data signal transmitted through the data line DL to the gate electrode of the second transistor T2, and the second transistor T2 is switched according to the data signal to adjust a current of the light emitting diode De.

The storage capacitor Cst maintains a charge corresponding to the data signal for one frame to keep the current flowing through the light emitting diode De constant and keep a gray level displayed by the light emitting diode De constant.

During a sensing period of one frame, the third transistor T3 is switched according to the gate signal transmitted through the gate line GL to supply the reference voltage to the source electrode of the second transistor T2. A voltage change of the source electrode of the second transistor T2 is sensed through the reference line RL, and a threshold voltage Vth of the second transistor T2 is calculated by comparing the voltage change with a judgment range.

As a result, the image data is compensated due to the threshold voltage Vth in real time, and a property change of the second transistor T2 is compensated to prevent deterioration of a display quality.

The sub-pixel configuration shown in FIG. 2 is merely an example, and each sub-pixel SP of the present disclosure can have one of other circuit configurations having different components and connections.

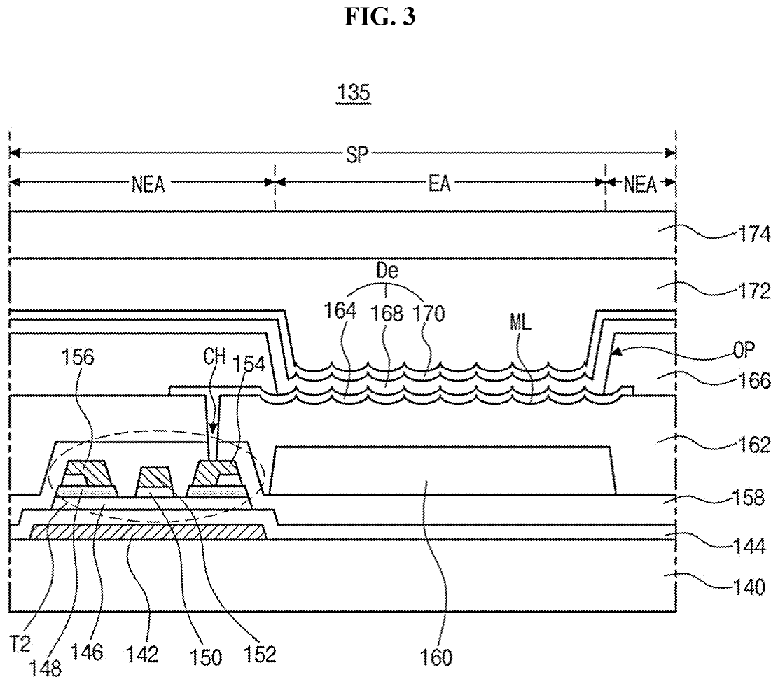

FIG. 3 is a cross-sectional view showing a display panel of an organic light emitting diode display device according to an embodiment of the present disclosure. The organic light emitting diode (OLED) display device can have a bottom emission type. The display panel of FIG. 3 shows an example of the display panel 135 of FIG. 1. The organic light emitting diode (OLED) display device may also have a top emission type or a dual emission type in another embodiment.

In FIG. 3, the display panel 135 of the OLED display device according to an embodiment of the present disclosure includes the second transistor T2 and a light emitting diode (LED) De in each subpixel SP on a substrate 140.

The substrate 140 includes the subpixel SP having an emission area EA and a non-emission area NEA. The LED De is disposed in the emission area EA, and the second transistor T2 is disposed in the non-emission area NEA.

A light shielding layer 142 is disposed in the non-emission area NEA on the substrate 140. The substrate 140 includes a transparent insulating material such as a glass and a plastic. For example, the plastic can include polyimide. In another embodiment, the substrate 140 may include glass, plastic, or a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example and is not necessarily limited thereto.

The light shielding layer 142 can have a single layer or a multiple layer of at least one of aluminum (Al), copper (Cu), molybdenum (Mo), titanium (Ti), chromium (Cr), nickel (Ni), tungsten (W) and an alloy thereof.

For example, the light shielding layer 142 can have a double layer of a lower layer of an alloy of molybdenum-titanium (MoTi) and an upper layer of copper (Cu), and a thickness of the upper layer can be greater than a thickness of the lower layer.

A buffer layer 144 is disposed on the light shielding layer 142 over an entire surface of the substrate 140, and may prevent moisture from permeating from the outside. The buffer layer 144 can have a single layer or a multiple layer of an inorganic insulating material such as silicon oxide (SiO2) and silicon nitride (SiNx). For example, the buffer layer 144 in a single layer may be a silicon oxide (SiOx) film or a silicon nitride (SiNx) film, and the buffer layer 144 in multiple layers may be formed by alternately stacking one or more silicon oxide (SiOx) films, one or more silicon nitride (SiNx) films, and one or more amorphous silicon (a-Si), but the present disclosure is not limited thereto.

A semiconductor layer 146 is disposed on the buffer layer 144 corresponding to the light shielding layer 142. The semiconductor layer 146 can include an oxide semiconductor material, and the light shielding layer 142 blocks a light incident to the semiconductor layer 146 to prevent deterioration of the semiconductor layer 146 due to the light. For example, the oxide semiconductor material may be formed of any one of indium gallium zinc oxide (IGZO), indium zinc oxide (IZO), indium gallium tin oxide (IGTO), and indium gallium oxide (IGO), but is not limited thereto.

Alternatively, the semiconductor layer 146 can include polycrystalline silicon, and both side portions of the semiconductor layer 146 can be doped with an impurity.

Connecting electrodes 148 are disposed on the side portions of the semiconductor layer 146, and a gate insulating layer 150 is disposed on a central portion of the semiconductor layer 146 exposed between the connecting electrodes 148. The connecting electrodes 148 can include a metallic material such as an alloy of molybdenum-titanium (MoTi). In another embodiment, the connecting electrodes 148 can be omitted.

The gate insulating layer 150 can be an insulating layer for insulating the semiconductor layer (or active layer) 146 and the gate electrode 152 from each other, and can include an inorganic insulating material such as silicon oxide (SiO2) and silicon nitride (SiNx). The gate insulating layer 150 can include silicon oxide (SiO2) when the semiconductor layer 146 includes an oxide semiconductor material, and the gate insulating layer 150 can include silicon oxide (SiO2) or silicon nitride (SiNx) when the semiconductor layer 146 includes polycrystalline silicon.

A gate electrode 152 is disposed on the gate insulating layer 150 corresponding to the central portion of the semiconductor layer 146, and source and drain electrodes 154 and 156 are disposed on the gate insulating layer 150 corresponding to both side portions, respectively, of the semiconductor layer 146. The source and drain electrodes 154 and 156 contact the connecting electrodes 148, respectively.

The gate insulating layer 150 and the gate electrode 152 can have the same shape or pattern as each other. In another embodiment, the gate insulating layer 150 can extend to cover the entire surface of the substrate 140.

The gate electrode 152 includes a conductive material such as a metal. For example, the gate electrode 152 can have a single layer or a multiple layer of at least one of aluminum (Al), copper (Cu), molybdenum (Mo), titanium (Ti), chromium (Cr), nickel (Ni), tungsten (W) and an alloy thereof.

For example, the gate electrode 152 can have a double layer of a lower layer of an alloy of molybdenum-titanium (MoTi) and an upper layer of copper (Cu), and a thickness of the upper layer can be greater than a thickness of the lower layer.

The semiconductor layer 146, the gate electrode 152, the source electrode 154 and the drain electrode 156 constitute the second transistor T2, and the second transistor T2 has a coplanar structure where the gate electrode 152, the source electrode 154 and the drain electrode 156 are disposed at one side of the semiconductor layer 146, i.e., over the semiconductor layer 146.

In another embodiment, the second transistor T2 can have an inverted staggered structure where the gate electrode is disposed under the semiconductor layer and the source and drain electrodes are disposed over the semiconductor layer. In the second transistor T2 of an inverted staggered structure, the semiconductor layer can include an oxide semiconductor material or amorphous silicon.

The first and third transistors T1 and T3 can have the same structure as the second transistor T2.

In another embodiment, the first, second and third transistors T1, T2 and T3 can have different structures from each other.

A passivation layer 158 is disposed on the gate electrode 152, the source electrode 154 and the drain electrode 156 over the entire surface of the substrate 140. The passivation layer 158 can include an inorganic insulating material such as silicon oxide (SiO2) and silicon nitride (SiNx). For example, the passivation layer 158, which is a kind of dielectric (e.g., an inorganic dielectric), may be constituted by a single layer made of a silicon oxide (SiOx) film, a silicon nitride (SiNx) film, or a silicon oxynitride (SiOxNy) film or a multilayer film thereof, etc.

A color filter layer 160 is disposed in the emission area EA on the passivation layer 158. The color filter layer 160 can include red, green and blue color filters.

An overcoat layer 162 is disposed on the color filter layer 160 over the entire surface of the substrate 140. The overcoat layer 162 and the passivation layer 158 have a contact hole CH exposing the source electrode 154. The overcoat layer 162 can include an organic insulating material such as photoacryl.

A plurality of microlenses ML are formed on a top surface of the overcoat layer 162 in the emission area EA. The plurality of microlenses ML constitute a microlens array (MLA), and each of the plurality of microlenses ML has a concave portion. A border portion of the two adjacent microlenses ML constitutes a convex portion, and each concave portion is surrounded by the convex portions. As a result, the microlens array can have a structure such that the concave portion and the convex portion are alternately disposed.

The overcoat layer 162 can have a substantially flat top surface in the non-emission area NEA.

A first electrode 164 including a conductive material having a relatively high work function is disposed on the overcoat layer 162 in the emission area EA. For example, the first electrode 164 can include a transparent conductive material such as indium tin oxide (ITO) and indium zinc oxide (IZO).

The first electrode 164 extends to the non-emission area NEA to contact the source electrode 154 through the contact hole CH.

The first electrode 164 is formed along a morphology of the top surface of the overcoat layer 162 having the microlens ML. As a result, the first electrode 164 has a top surface of an uneven shape.

A bank layer 166 is disposed on the first electrode 164. The bank layer 166 can include an organic insulating material and overlaps an edge portion of the first electrode 164 to cover the edge portion of the first electrode 164. The bank layer 166 has an open portion OP corresponding to the emission area EA, and a central portion of the first electrode 164 is exposed through the open portion OP.

An emitting layer 168 is disposed on the central portion of the first electrode 164 exposed through the open portion OP of the bank layer 166. The emitting layer 168 is disposed over substantially the entire surface of the substrate 140. As a result, the emitting layer 168 is disposed on the first electrode 164 in the emission area EA to contact the first electrode 164 and is disposed on the bank layer 166 in the non-emission area NEA to contact a top surface of the bank layer 166. Further, the emitting layer 168 contacts a side surface of the bank layer 166. For example, the emitting layer 168 may be formed in the open portion OP of the bank layer 166, and not extend to be disposed on an upper surface of the bank layer 166 in the non-emission area NEA.

The emitting layer 168 emits a white colored light and includes at least one hole auxiliary layer, at least one emitting material layer and at least one electron auxiliary layer constituting one emitting unit. The hole auxiliary layer can include at least one of a hole injecting layer (HIL) and a hole transporting layer (HTL), and the electron auxiliary layer can include at least one of an electron injecting layer (EIL) and an electron transporting layer (ETL).

The emitting layer 168 can have a stack structure where two or more emitting units emitting different colored lights are laminated, and a charge generating layer can be disposed between the two or more emitting units.

The emitting layer 168 is formed along a morphology of a top surface of the first electrode 164 in the emission area EA. As a result, the emitting layer 168 is formed along the morphology of the top surface of the overcoat layer 162 in the emission area EA to have a top surface of an uneven shape.

A second electrode 170 including a conductive material having a relatively low work function is disposed on the emitting layer 168 over the entire surface of the substrate 140. The second electrode 170 is disposed over the first electrode 164 in the emission area EA and is disposed over the bank layer 166 in the non-emission area NEA.

For example, the second electrode 170 can include one of aluminum (Al), magnesium (Mg), silver (Ag) and an alloy thereof.

The second electrode 170 is formed along a morphology of a top surface of the emitting layer 168 in the emission area EA. As a result, the second electrode 170 is formed along a morphology of the top surface of the overcoat layer 162 in the emission area EA to have a top surface of an uneven shape.

A thickness of the emitting layer 168 corresponding to the concave portion of the microlens ML is greater than a thickness of the emitting layer 168 corresponding to the convex portion where the two microlenses ML are disposed adjacent to each other. The emitting layer 168 can have a minimum thickness between the concave portion and the convex portion.

The first electrode 164, the emitting layer 168 and the second electrode 170 constitute the light emitting diode De. The first electrode 164 can be an anode, and the second electrode 170 can be a cathode.

The first electrode 164 includes a transparent conductive material where a light passes and the second electrode 170 includes a metallic material where a light is reflected. As a result, a light from the emitting layer 168 passes through the first electrode 164, the color filter layer 160 and the substrate 140 to be emitted to an exterior.

An encapsulating layer 172 is disposed on the second electrode 170 over the entire surface of the substrate 140. The encapsulating layer 172 can have a shape of a face seal including an organic insulating material or an inorganic insulating material that is transparent and has an adhesive property. Alternatively, the encapsulating layer 172 can have a multiple layer where an inorganic layer, an organic layer and an inorganic layer are alternately laminated.

A counter substrate 174 is disposed on the encapsulating layer 172. The counter substrate 174 can include one of a glass and a metallic material or can have a film shape.

The encapsulating layer 172 and the counter substrate 174 prevents an oxygen or a moisture of an exterior from penetrating into an interior and prevents an impact of an exterior from being delivered to the light emitting diode De.

In the display panel 135 of the OLED display device 110 according to an embodiment of the present disclosure, the overcoat layer 162 has the plurality of microlenses ML on the top surface thereof in the emission area EA, and the first electrode 164, the emitting layer 168 and the second electrode 170 over the overcoat layer 162 are formed along the morphology of the top surface of the overcoat layer 162. As a result, the first electrode 164, the emitting layer 168 and the second electrode 170 in the emission area EA have an uneven pattern corresponding to the microlens ML of the overcoat layer 162, i.e., a microlens.

A light emitted from the emitting layer 168 can be dissipated through a total reflection. Since the microlens ML changes a path of the light, the light is extracted to an exterior and a light extraction efficiency is improved.

The microlens ML has a relatively small size of a few micrometers. Since a size and a shape of the microlens ML directly influence a luminance, a management of the size and the shape is required.

As a result, the OLED display device 110 according to an embodiment of the present disclosure includes a measurement hole MH and a measurement groove MG to measure and manage a thickness of a photoresist pattern for forming the microlens ML, which will now be discussed in more detail.

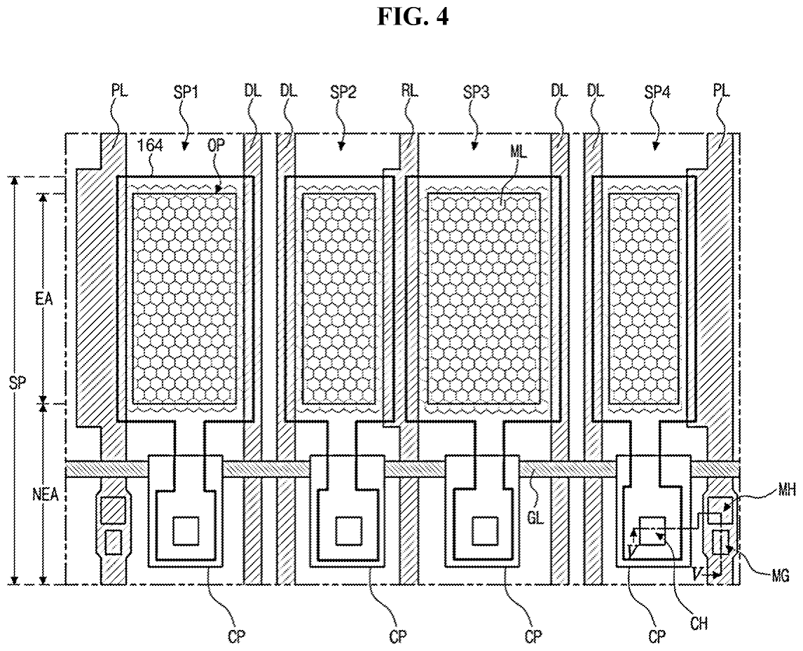

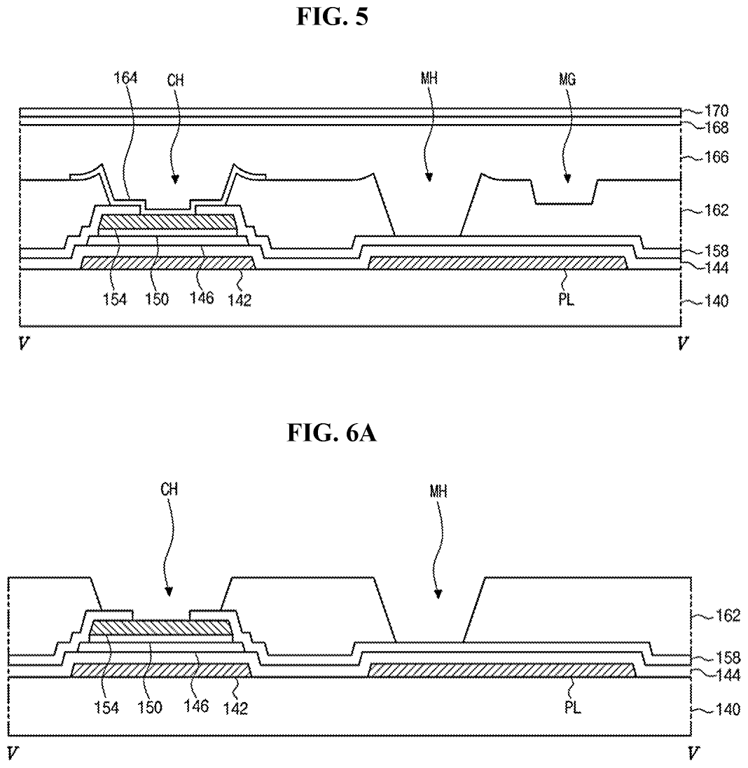

FIG. 4 is a plan view showing a pixel of a display panel of an organic light emitting diode display device according to an embodiment of the present disclosure, and FIG. 5 is a cross-sectional view taken along a line V-V of FIG. 4.

In FIG. 4, the OLED display device 110 includes the gate line GL, the data line DL, the power line PL and the reference line RL. The gate line GL is disposed along a first direction of a horizontal direction, and the data line DL, the power line PL and the reference line RL are disposed along a second direction of a vertical direction. The gate line GL crosses the data line DL, the power line PL and the reference line RL to define the first, second, third and fourth subpixels SP1, SP2, SP3 and SP4.

One reference line RL is disposed between two power lines PL, and the data lines DL are disposed between one power line PL and one reference line RL. Each of the first, second, third and fourth subpixels SP1, SP2, SP3 and SP4 can have a tetragonal shape. In another embodiment, a shape of each of the first, second, third and fourth subpixels SP1, SP2, SP3 and SP4 can vary.

For example, one pixel P can include the first, second, third and fourth subpixels SP1, SP2, SP3 and SP4, and the first, second, third and fourth subpixels SP1, SP2, SP3 and SP4 can be sequentially disposed along the first direction.

The first, second, third and fourth subpixels SP1, SP2, SP3 and SP4 correspond to red, blue, white and green colors, respectively. In another embodiment, the number of the subpixels of one pixel and the arrangement order of the red, blue, white and green subpixels can vary.

Areas of the first, second, third and fourth subpixels SP1, SP2, SP3 and SP4 can be different from each other. For example, the areas of the first and third subpixels SP1 and SP3 can be greater than the areas of the second and fourth subpixels SP2 and SP4. The area of the third subpixel SP3 can be equal to or greater than the area of the first subpixel SP1, and the area of the second subpixel SP2 can be equal to or greater than the area of the fourth subpixel SP4. In another embodiment, the area relation of the first, second, third and fourth subpixels SP1, SP2, SP3 and SP4 can vary, and the areas of the first, second, third and fourth subpixels SP1, SP2, SP3 and SP4 can be the same as each other.

One power line PL, two data lines DL or one reference line RL is disposed between the two adjacent subpixels SP1, SP2, SP3 and SP4. For example, two data lines DL can be disposed between the first and second subpixels SP1 and SP2 and between the third and fourth subpixels SP3 and SP4, one reference line RL can be disposed between the second and third subpixels SP2 and SP3, and one power line PL can be disposed between the fourth subpixel SP4 and the first subpixel SP1 of the next pixel.

Each of the first, second, third and fourth subpixels SP1, SP2, SP3 and SP4 includes the emission area EA and the non-emission area NEA. The light emitting diode De is disposed in the emission area EA of each of the first, second, third and fourth subpixels SP1, SP2, SP3 and SP4, and a circuit part CP is disposed in the non-emission area NEA of each of the first, second, third and fourth subpixels SP1, SP2, SP3 and SP4. The light emitting diode De includes the first electrode 164 of an anode, and the circuit part CP includes the first, second and third transistors T1, T2 and T3 and the storage capacitor Cst.

The first electrode 164 extends to the non-emission area NEA to be electrically connected to the circuit part CP. For example, the first electrode 164 can be electrically connected to the second transistor T2 of the circuit part CP through the contact hole CH. The source electrode 154 of the second transistor T2 can be exposed through the contact hole CH, and the first electrode 164 can contact the source electrode 154 of the second transistor T2 through the contact hole CH.

The emission area EA can be defined by the open portion OP of the bank layer 166 exposing the first electrode 164. The open portion OP of the bank layer 166 has an area smaller than an area of the first electrode 164 and is disposed inside a boundary of the first electrode 164.

The power line PL, the data line DL and the reference line RL can overlap the first electrode 164 and can be spaced apart from the open portion OP of the bank layer 166. A width of a portion of each of the power line PL and the reference line RL overlapping the first electrode 164 can be greater than a width of the other portion of each of the power line PL and the reference line RL.

The plurality of microlenses ML are disposed in the emission area EA of each of the first, second, third and fourth subpixels SP1, SP2, SP3 and SP4. The microlens ML is disposed outside the open portion OP as well as inside the open portion OP and overlaps the bank layer 166. The microlens ML overlaps the first electrode 164 and is spaced apart from the boundary of the first electrode 164 without overlapping.

The microlens ML can have a hexagonal shape in a plan view to constitute a honeycomb structure. In another embodiment, the microlens ML can have a circular shape, an elliptical shape and a tetragonal shape.

In the OLED display device 110 according to an embodiment of the present disclosure, the contact hole CH is disposed in the circuit part CP of each of the first, second, third and fourth subpixels SP1, SP2, SP3 and SP4, and a measurement hole MH and a measurement groove MG are disposed over the power line PL.

In FIG. 5, the light shielding layer 142 is disposed in the circuit part CP of each of the first, second, third and fourth subpixels SP1, SP2, SP3 and SP4 on the substrate 140, and the power line PL is disposed between the adjacent two of the first, second, third and fourth subpixels SP1, SP2, SP3 and SP4 on the substrate 140.

The light shielding layer 142 and the power line PL can have the same layer and the same material as each other.

The buffer layer 144 is disposed on the light shielding layer 142 and the power line PL over the entire surface of the substrate 140, and the semiconductor layer 146 is disposed on the buffer layer 144 corresponding to the light shielding layer 142.

The gate insulating layer 150 is disposed on the semiconductor layer 146, and the source electrode 154 is disposed on the gate insulating layer 150.

The passivation layer 158 is disposed on the source electrode 154 over the entire surface of the substrate 140, and the overcoat layer 162 is disposed on the passivation layer 158.

The overcoat layer 162 and the passivation layer 158 have the contact hole CH exposing the source electrode 154, and the overcoat layer 162 has the measurement hole MH exposing the passivation layer 158 corresponding to the power line PL and the measurement groove MG corresponding to the power line PL and having a concave shape.

The measurement hole MH and the measurement groove MG of the overcoat layer 162 are disposed directly over the power line PL to be spaced apart from each other. Each of the measurement hole MH and the measurement groove MG of the overcoat layer 162 has a width greater than a diameter of an incident light of a spectroscope to receive a sufficient amount of the incident light. A connecting portion of a top surface of the overcoat layer 162 and a sidewall of the contact hole CH and the measurement hole MH has a sharp shape having an acute angle.

For example, the measurement hole MH and the measurement groove MG of the overcoat layer 162 can be spaced apart from each other by a gap distance equal to or greater than about 4.5 μm, and each of the measurement hole MH and the measurement groove MG of the overcoat layer 162 can have a width equal to or greater than of about 12 μm.

Since the measurement groove MG of the overcoat layer 162 is disposed over the power line PL corresponding to each of the first, second, third and fourth subpixels SP1, SP2, SP3 and SP4, a size and a shape of the measurement groove MG of the overcoat layer 162 are accurately measured. Further, the measurement groove MG of the overcoat layer 162 has a shape corresponding to the plurality of microlenses ML on the top surface of the overcoat layer 162. For example, a bottom surface of the measurement groove MG may be formed to have a shape or pattern corresponding to that of the plurality of microlenses ML. As a result, the measurement groove MG of the overcoat layer 162 can be used for monitoring the plurality of microlenses ML on the top surface of the overcoat layer 162 in the emission area EA. In another example, since the measurement hole MH passes through the overcoat layer 162 and exposes a layer (e.g., the passivation layer 158) under the overcoat layer 162, the measurement hole MH may not have a shape corresponding to the plurality of microlenses ML.

In an example of FIG. 5, the measurement hole MH and the measurement groove MG of the overcoat layer 162 are exemplarily disposed over the power line PL having the same layer and the same material as the light shielding layer 142. For example, one of the measurement hole MH and the measurement groove MG of the overcoat layer 162 may be selectively disposed. In another embodiment, the measurement hole MH and the measurement groove MG of the overcoat layer 162 can be disposed over the power line having the same layer and the same material as one of the gate electrode, the source electrode and the drain electrode, or can be disposed over one of the gate line, the data line and the reference line having the same layer and the same material as one of the light shielding layer, the gate electrode, the source electrode and the drain electrode. In yet another embodiment, one of the measurement hole MH and the measurement groove MG may be disposed over one of the power line, the gate line, the data line and the reference line, and other of the measurement hole MH and the measurement groove MG may be disposed over a different one of the power line, the gate line, the data line and the reference line. The power line, the gate line, the data line and the reference line may be collectively referred to as conductive lines electrically connected to the circuit part CP.

The top surface of the overcoat layer 162 in the emission area EA includes the plurality of microlenses ML.

The first electrode 164 is disposed on the overcoat layer 162 corresponding to the light shielding layer 142 and is connected to the source electrode 154 exposed through the contact hole CH in the overcoat layer 162 and the passivation layer 158.

The bank layer 166 is disposed on the first electrode 1164 and the overcoat layer 162, and the emitting layer 168 and the second electrode 170 are sequentially disposed on the bank layer 166.

In the OLED display device 110 according to an embodiment of the present disclosure, after a photoresist pattern is formed on the overcoat layer 162 through a coating, an exposure and a development of a photoresist, the microlens ML is formed on the top surface of the overcoat layer 162 through an ashing step of the photoresist pattern and the overcoat layer 162.

A thickness of the photoresist pattern and the overcoat layer 162 and an ashing amount of the photoresist pattern and the overcoat layer can be accurately measured using the measurement hole MH and the measurement groove MG of the overcoat layer 162.

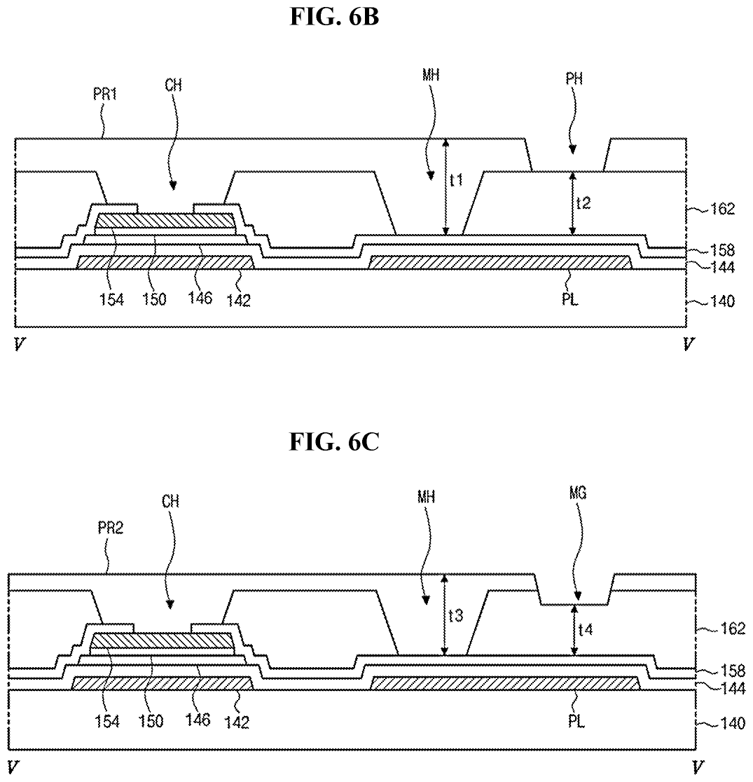

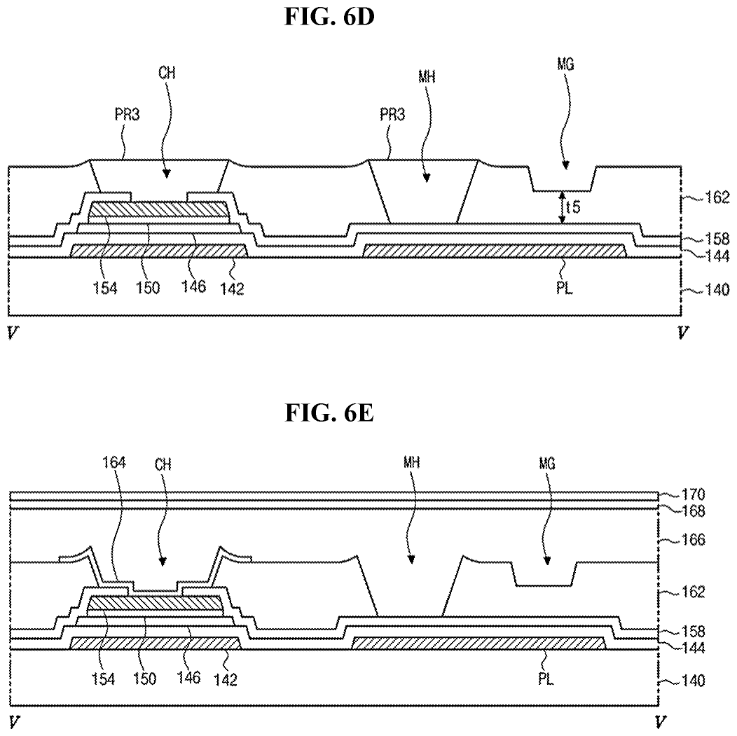

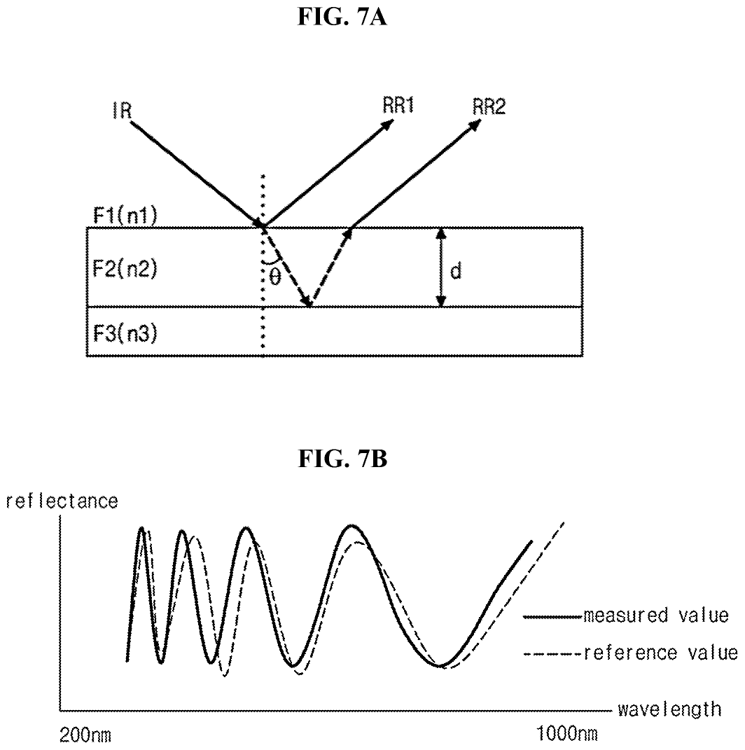

FIGS. 6A to 6E are cross-sectional views showing a method of fabricating an organic light emitting diode display device according to an embodiment of the present disclosure, and FIGS. 7A and 7B are views showing a method of measuring a thickness of an organic light emitting diode display device according to an embodiment of the present disclosure.

In FIG. 6A, the light shielding layer 142 is formed in the circuit part CP of each of the first, second, third and fourth subpixels SP1, SP2, SP3 and SP4 on the substrate 140, and the power line PL is formed between the adjacent two of the first, second, third and fourth subpixels SP1, SP2, SP3 and SP4 on the substrate 140.

Next, the buffer layer 144 is formed on the light shielding layer 142 and the power line PL over the entire surface of the substrate 140, and the semiconductor layer 146 is formed on the buffer layer 144 corresponding to the light shielding layer 142.

Next, the gate insulating layer 150 is formed on the semiconductor layer 146, and the source electrode 154 is formed on the gate insulating layer 150.

Next, the passivation layer 158 is formed on the source electrode 154 over the entire surface of the substrate 140, and the overcoat layer 162 having the contact hole CH corresponding to the source electrode 154 and the measurement hole MH corresponding to the power line PL is formed on the passivation layer 158.

For example, an overcoat material layer can be formed on the passivation layer 158 by coating a photosensitive insulating material, and the contact hole CH and the measurement hole MH can be formed in the overcoat material layer by exposing the overcoat material layer through an exposure mask and developing the exposed overcoat material layer. Then, the source electrode 154 can be exposed by etching the passivation layer 158 in the contact hole CH to form the overcoat layer 162 having the contact hole CH and the measurement hole MH.

In FIG. 6B, a first photoresist pattern PR1 having a photoresist hole PH exposing the overcoat layer 162 corresponding to the power line PL is formed on the overcoat layer 162.

For example, a photoresist layer can be formed on the overcoat layer 162 by coating a photoresist, and the photoresist hole PH can be formed in the photoresist layer by exposing the photoresist layer through an exposure mask and developing the exposed photoresist layer to form the first photoresist pattern PR1 having the photoresist hole PH.

The first photoresist pattern PR1 fills the measurement hole MH of the overcoat layer 162 to directly contact the passivation layer 158 corresponding to the power line PL. A first thickness t1 of the first photoresist pattern PR1 can be accurately detected by irradiating an incident light of a spectrometer onto the first photoresist pattern PR1 and by measuring an interference fringe of a reflected light.

The overcoat layer 162 is exposed through the photoresist hole PH of the first photoresist pattern PR1. A second thickness t2 of the overcoat layer 162 can be accurately detected by irradiating an incident light of a spectrometer onto the overcoat layer 162 and by measuring an interference fringe of a reflected light.

The first thickness t1 of the first photoresist pattern PR1 and the second thickness t2 of the overcoat layer 162 can be measured or determined by a spectrometer using an interference of the reflected light.

In FIG. 7A, first to third films (media) F1 to F3 having first to third refractive indexes n1 to n3, respectively, are laminated. When an incident light IR of a spectrometer is incident to an interface between the first and second films F1 and F2, a portion of the incident light IR is reflected on an incident point as a first reflected light RR1. Another portion of the incident light IR is refracted at the interface between the first and second films F1 and F2 with a refraction angle θ and then is reflected at an interface between the second and third films F2 and F3. Then, the another portion of the incident light passes through the interface between the first and second films F1 and F2 to be emitted as a second reflected light RR2.

The first and second reflected lights RR1 and RR2 have a light path difference ΔLp according to the refraction angle θ and a thickness d of the second film F2 (ΔLp=2*n2*d*cos θ) and destructively and constructively interfere with each other to generate an interference fringe.

In FIG. 7B, after the incident light IR of the spectrometer is irradiated onto the interface between the first and second films F1 and F2, the reflected lights RR1 and RR2 are measured and the interference fringe of a measured value is calculated. The calculated interference fringe is compared with interference fringes of reference values according to a thickness d of the second film F2, and the thickness d of the second film F2 is calculated by selecting the interference value most similar to the calculated interference fringe.

When a method of measuring or determining a thickness in a spectrometer is applied to the OLED display device 110, the first film F1 can correspond to the air over the first photoresist pattern PR1, and the second and third films F2 and F3 can correspond to the first photoresist pattern PR1 and the overcoat layer 162, respectively.

When the overcoat layer 162 does not have the measurement hole MH, since a refractive index of the first photoresist pattern PR1 is similar to a refractive index of the overcoat layer 162, a light is not sufficiently reflected at the interface between the first photoresist pattern PR1 and the overcoat layer 162. As a result, the interference fringe is not clearly generated, and a measurement accuracy for a thickness of the first photoresist pattern PR1 is deteriorated.

For example, the first photoresist pattern PR1 can have a refractive index of about 1.64, and the overcoat layer 162 can have a refractive index of about 1.55.

Further, since the first photoresist pattern PR1 and the overcoat layer 162 have a relatively great total thickness, a measurement error can occur.

In the OLED display device 110 according to an embodiment of the present disclosure, the overcoat material of the measurement hole MH of the overcoat layer 162 is removed, and the first photoresist pattern PR1 fills the measurement hole MH of the overcoat layer 162. As a result, the first photoresist pattern PR1 remains in the measurement hole MH without the overcoat layer 162. Since the first photoresist pattern PR1 corresponds to the power line PL having a relatively great refractive index difference (the buffer layer 144 and the passivation layer 158 can be neglected because the buffer layer 144 and the passivation layer 158 have a relatively small thickness as compared with the overcoat layer 162 and the first photoresist pattern PR1), the first thickness t1 of the first photoresist pattern PR1 is accurately measured and managed by irradiating the incident light IR of the spectrometer onto the first photoresist pattern PR1 corresponding to the measurement hole MH.

Further, the photoresist material of the photoresist hole PH of the first photoresist pattern PR1 is removed, and the overcoat layer 162 is exposed through the photoresist hole PH without the first photoresist pattern PR1. Since the overcoat layer 162 corresponds to the power line PL having a relatively great refractive index difference (the buffer layer 144 and the passivation layer 158 can be neglected because the buffer layer 144 and the passivation layer 158 have a relatively small thickness as compared with the overcoat layer 162 and the first photoresist pattern PR1), the second thickness t2 of the overcoat layer 162 is accurately measured and managed by irradiating the incident light IR of the spectrometer onto the overcoat layer 162 corresponding to the photoresist hole PH.

When the thickness of the first photoresist pattern PR1 exceeds a tolerance range, a surface shape of the photoresist pattern is changed before and after a subsequent ashing step, and a shape of the microlens ML on the top surface of the overcoat layer 162 in the emission area EA is changed. As a result, the light extraction efficiency can be reduced.

Accordingly, when the measured first thickness t1 of the first photoresist pattern PR1 exceeds the tolerance range, a process optimization is obtained and a yield is improved by removing the first photoresist pattern PR1 and performing a rework.

In FIG. 6C, the first photoresist pattern PR1 and the overcoat layer 162 are partially removed by performing a first ashing step to the first photoresist pattern PR1 and the overcoat layer 162. As a result, a second photoresist pattern PR2 having a thickness smaller than the first thickness t1 of the first photoresist pattern PR1 is formed, and the measurement groove MG corresponding to the photoresist hole PH is formed in the overcoat layer 162. The photoresist hole PH of the first photoresist pattern PR1 is maintained in the second photoresist pattern PR2.

A third thickness t3 of the second photoresist pattern PR2 is accurately detected by irradiating the incident light of the spectrometer onto the second photoresist pattern PR2 in the measurement hole MH and measuring the interference fringe of the reflected light. Since the first photoresist pattern PR1 is partially removed by the first ashing step, the third thickness t3 of the second photoresist pattern PR2 is smaller than the first thickness t1 of the first photoresist pattern PR1.

The measurement groove MG of the overcoat layer 162 is exposed through the photoresist hole PH of the second photoresist pattern PR2. A fourth thickness t4 of the overcoat layer 162 corresponding to the measurement groove MG is accurately detected by irradiating the incident light of the spectrometer onto the overcoat layer 162 of the measurement groove MG exposed through the photoresist hole PH and measuring the interference fringe of the reflected light. Since the overcoat layer 162 is partially removed by the first ashing step, the fourth thickness t4 of the overcoat layer 162 of the measurement groove MG is smaller than the second thickness t2 of the other portion of the overcoat layer 162.

An ashing amount of the photoresist pattern can be calculated from a value obtained by subtracting the third thickness t3 of the second photoresist pattern PR2 from the first thickness t1 of the first photoresist pattern PR1, and an ashing rate ARp of the photoresist pattern can be calculated by dividing the ashing amount of the photoresist pattern by a process time Ta1 of the first ashing step. That is, an equation of Arp=(t1−t3)/Ta1 can be provided.

An ashing amount of the overcoat layer 162 can be calculated from a value obtained by subtracting the fourth thickness t4 of the overcoat layer 162 of the measurement groove MG from the second thickness t2 of the overcoat layer 162, and an ashing rate ARo of the overcoat layer 162 can be calculated by dividing the ashing amount of the overcoat layer 162 by a process time Ta1 of the first ashing step. That is, an equation of ARo=(t2−t4)/Ta1 can be provided. For example, the process time Ta1 of the first ashing step can be about 100 sec.

In FIG. 6D, the second photoresist pattern PR2 and the overcoat layer 162 are partially removed by performing a second ashing step to the second photoresist pattern PR2 and the overcoat layer 162. As a result, a third photoresist pattern PR3 having a thickness smaller than the thickness of the second photoresist pattern PR2 is formed, and a thickness of the overcoat layer 162 of the measurement groove MG is reduced. The third photoresist pattern PR3 fills the contact hole CH and the measurement hole MH, and the top surface of the overcoat layer 162 is exposed.

A fifth thickness t5 of the overcoat layer 162 of the measurement groove MG is accurately detected by irradiating the incident light of the spectrometer onto the overcoat layer 162 of the measurement groove MG and measuring the interference fringe of the reflected light. Since the overcoat layer 162 is partially removed by the second ashing step, the fifth thickness t5 of the overcoat layer 162 of the measurement groove MG is smaller than the second thickness t2 of the other portion of the overcoat layer 162 and is smaller than the fourth thickness t4 of the overcoat layer 162 of the measurement groove MG after the first ashing step.

A total ashing amount of the overcoat layer 162 can be calculated or determined from a value obtained by subtracting the fifth thickness t5 of the overcoat layer 162 of the measurement groove MG after the second ashing step from the second thickness t2 of the overcoat layer 162. For example, the process time Ta2 of the second ashing step can be about 260 sec.

After the second ashing step, the microlens ML is formed on the overcoat layer 162 in the emission area EA.

In FIG. 6E, after the third photoresist pattern PR3 is removed, the first electrode 164 is formed on the overcoat layer 162 corresponding to the light shielding layer 142 and the bank layer 166 is formed on the first electrode 164 and the overcoat layer 162. The bank layer 166 can be disposed on the overcoat layer 162 to fill the measurement hole MH and the measurement groove MG.

Next, the emitting layer 168 and the second electrode 170 are sequentially formed on the bank layer 166.

Consequently, in the OLED display device 110 and the method of fabricating the OLED display device 110 according to an embodiment of the present disclosure, the measurement hole MH corresponding to the power line PL is formed in the overcoat layer 162, and the photoresist pattern directly contacting the passivation layer 158 is measured through the measurement hole MH. As a result, the thickness of the photoresist pattern, the ashing amount and the ashing rate are accurately detected, managed and monitored.

Further, the photoresist hole PH corresponding to the power line PL is formed in the photoresist pattern, and the overcoat layer exposed through the photoresist hole PH is measured. As a result, the thickness of the overcoat layer 162, the ashing amount and the ashing rate are accurately detected, managed and monitored.

As a result, in the present disclosure, a shape change of the microlens and a reduction of the light extraction efficiency are minimized, the process optimization is obtained, and the yield is improved. In addition, the product energy is reduced, and a material recycling due to the rework is obtained.

It will be apparent to those skilled in the art that various modifications and variation can be made in the present disclosure without departing from the scope of the disclosure. Thus, it is intended that the present disclosure cover the modifications and variations of this disclosure provided they come within the scope of the appended claims.

What is claimed is:

1. An organic light emitting diode display device, comprising:
a subpixel on a substrate;
a circuit part in the subpixel on the substrate;
a plurality of conductive lines connected to the circuit part;
an overcoat layer on the plurality of conductive lines, the overcoat layer having a measurement hole corresponding to at least one of the plurality of conductive lines; and
a light emitting diode on the overcoat layer, the light emitting diode connected to the circuit part.

2. The organic light emitting diode display device of claim 1, further comprising a bank layer disposed on the overcoat layer and filling the measurement hole of the overcoat layer.

3. The organic light emitting diode display device of claim 1, wherein the overcoat layer has a measurement groove corresponding to at least one of the plurality of conductive lines, and
wherein the measurement groove is spaced apart from the measurement hole.

4. The organic light emitting diode display device of claim 1, wherein the circuit part comprises:
a light shielding layer;
a buffer layer on the light shielding layer;
a transistor on the buffer layer; and
a passivation layer on the transistor,
wherein the measurement hole exposes a top surface of the passivation layer corresponding to at least one of the plurality of conductive lines.

5. The organic light emitting diode display device of claim 4, wherein the plurality of conductive lines include one or more of a gate line, a data line, a power line and a reference line.

6. The organic light emitting diode display device of claim 4, wherein the power line has a same layer and a same material as the light shielding layer, and
wherein the measurement hole is disposed over the power line.

7. The organic light emitting diode display device of claim 3, further comprising:
a plurality of microlenses on the overcoat layer and corresponding to the light emitting diode.

8. The organic light emitting diode display device of claim 7, wherein the measurement groove has a shape corresponding to the plurality of microlenses and is used for monitoring the plurality of microlenses.

9. The organic light emitting diode display device of claim 1, wherein the measurement hole has a width greater than a diameter of an incident light of a spectrometer.

10. The organic light emitting diode display device of claim 1, wherein a connecting portion of a top surface of the overcoat layer and a sidewall of the measurement hole has a sharp shape having an acute angle.

11. The organic light emitting diode display device of claim 3, further comprising:
a passivation layer disposed between the overcoat layer and the power line,
wherein the measurement hole exposes a portion of the passivation layer corresponding to the power line.

12. The organic light emitting diode display device of claim 3, wherein both the measurement hole and the measurement groove are disposed above the power line.

13. The organic light emitting diode display device of claim 3, wherein the measurement hole is a thru-hole and the measurement grove is an indentation.

14. A method of fabricating an organic light emitting diode display device, the method comprising:
forming a circuit part in a subpixel on a substrate;
forming a plurality of conductive lines that are connected to the circuit part;
forming an overcoat layer having a measurement hole corresponding to at least one of the plurality of conductive lines on the plurality of conductive lines; and
forming a light emitting diode connected to the circuit part on the overcoat layer.

15. The method of claim 14, further comprising:
forming a first photoresist pattern having a photoresist hole on the overcoat layer, the photoresist hole exposing the overcoat layer corresponding to at least one of the plurality of conductive lines;
forming a second photoresist pattern on the overcoat layer and a measurement groove in the overcoat layer by performing a first ashing step to the first photoresist pattern and the overcoat layer, wherein the measurement groove corresponds to the photoresist hole; and
forming a third photoresist pattern by performing a second ashing step to the second photoresist pattern and the overcoat layer, wherein the third photoresist pattern exposes a top surface of the overcoat layer.

16. The method of claim 15, further comprising:
determining a first thickness of the first photoresist pattern by irradiating an incident light of a spectrometer onto the first photoresist pattern corresponding to the measurement hole;
determining a second thickness of the overcoat layer by irradiating the incident light of the spectrometer onto the overcoat layer corresponding to the photoresist hole;
determining a third thickness of the second photoresist pattern by irradiating the incident light of the spectrometer onto the second photoresist pattern corresponding to the measurement hole;
determining a fourth thickness of the overcoat layer of the measurement groove by irradiating the incident light of the spectrometer onto the overcoat layer of the measurement groove exposed through the photoresist hole of the second photoresist pattern; and
determining a fifth thickness of the overcoat layer of the measurement groove by irradiating the incident light of the spectrometer onto the overcoat layer onto the overcoat layer of the measurement groove exposed through the third photoresist pattern.

17. The method of claim 16, wherein each of the measurement hole and the measurement groove has a width greater than a diameter of the incident light of the spectrometer.

18. The method of claim 16, further comprising:
determining an ashing amount of the first photoresist pattern from a value obtained by subtracting the third thickness from the first thickness;
determining an ashing rate of the first photoresist pattern by dividing the ashing amount of the first photoresist pattern by a process time of the first ashing step;
determining an ashing amount of the overcoat layer from a value obtained by subtracting the fourth thickness from the second thickness;
determining an ashing rate of the overcoat layer by dividing the ashing amount of the overcoat layer by the process time of the first ashing step; and
determining a total ashing amount of the overcoat layer from a value obtained by subtracting the fifth thickness from the second thickness.

19. The method of claim 15, wherein the forming the overcoat layer includes:
forming a plurality of microlenses on a top surface of the overcoat layer corresponding to the light emitting diode.

20. The method of claim 19, further comprising:
monitoring the plurality of microlenses by measuring the measurement groove having a shape corresponding to the plurality of microlenses.
